(19) United States
(12) Patent Application Publication
(10) Pub. No.: US 2008/0029761 A1
(43) Pub. Date: Feb. 7, 2008

(54) Through-hole vertical semiconductor devices or chips

(75) Inventor: Yi Fang Peng, Beijing (CN)

Correspondence Address: Hui Peng, 35964 Vivian PL, Fremont, CA, 94536, US

(73) Assignees: Peng Jing; Yi Fang Peng; Hui Peng

(21) Appl. No.: 11/881,872

(22) Filed: Jul. 30, 2007

(30) Foreign Application Priority Data
Aug. 1, 2006 (CN) 200610089061.5

(51) Int. Cl. H01L 33/00

(52) U.S. Cl. 257/43; 257/98; 438/27; 257/E33.013

(57) ABSTRACT

The present invention discloses through-hole vertical semiconductor devices and chips. The structure of an embodiment of through-hole vertical semiconductor devices and chips having static protection diodes is the following: a semiconductor epitaxial layer is bonded to the first surface of a supporting chip with static protection diode; the first-type cladding layer of the semiconductor epitaxial layer is electrically connected to a first electrode on the second surface of the supporting chip via a current spreading layer, a patterned electrode, a half-through-hole-metal-plug and a through-hole-metal-plug; the second-type cladding layer of the semiconductor epitaxial layer is electrically connected to a second electrode on the second surface of the supporting chip via a reflector/Ohmic/bonding layer and at least one through-hole-metal-plug. An external power source is electrically connected to the first and second electrodes without wire bonding.

### BACKGROUND OF THE INVENTION

(1) Field of the Invention

The present invention discloses through-hole vertical semiconductor devices or chips comprising through-hole vertical semiconductor GaN based, GaP based, GaNP based and ZnO based devices or chips (comprising through-hole vertical GaN based, GaP based, GaNP based and ZnO based LED) and low cost methods of manufacturing the same.

(2) Prior Art

High power semiconductor devices or chips comprising GaN based, GaP based, GaNP based and ZnO based devices or chips (comprising GaN based, GaP based, GaNP based and ZnO based LEDs) have huge market. However, (1) technical and manufacturing issues (including heat dissipation and yield) need to be resolved; (2) performance and reliability need to be continuously improved; (3) products become smaller, thinner and lighter. In order to resolve the issues mentioned above, several methods have been disclosed, comprising: (1) vertical GaP based LED chips are disclosed to resolve the absorption of emitting light of GaAs growth substrate; (2) vertical GaN based LED are disclosed to resolve the low heat dissipation of sapphire growth substrates. The basic manufacturing process and structure of vertical semiconductor devices or chips are the following: depositing a reflector/Ohmic/bonding layer on the epitixial layer of a semiconductor epitixial wafer, bonding the reflector/Ohmic/bonding layer to an electrically conductive supporting substrate, removing the original growth substrate, depositing electrodes on the exposed epitaxial layer to form vertical semiconductor chips. However there is at least one wire to be bonded to a vertical chip for connecting the chip to an external power source. Wire bonding causes reliability issue, thicker packages and complicated packaging process. Also burn-in process has to be done after packaging the chips, which causes uncertainty of chip quality before packaging. Once the chip is not qualified, then the whole package is failed and hard to re-work, and the cost is increasing.

The present invention discloses a through-hole vertical semiconductor devises or chips with or without static protection diodes and methods of manufacturing the same.

### BRIEF SUMMARY OF THE INVENTION

The present invention discloses through-hole vertical semiconductor devises or chips (with or without static protection diodes built-in). An embodiment of the structure of through-hole vertical semiconductor devise or chip with static protection diodes comprises (FIG. 1f): second and first electrodes 110 and 111 formed on the second surface of silicon supporting substrate 106; second and first electrodes 110 and 111 being not directly contacted to each other; metal layer 107 deposited on the first surface of silicon supporting substrate 106 being electrically connected to second electrode 110 via through-hole-metal-plug 108; static protection diode 112 built-in silicon supporting substrate 106; through-hole-metal-plug 109 electrically connected to first electrode 111; metal layer 107 and through-hole-metal-plug 109 electrically connected to two polarities of static protection diode 112 respectively; the shape and position of metal layer 107 corresponding to that of reflector/Ohmic/bonding layer 105; the shape and position of through-hole-metal-plug 109 corresponding to that of half-through-hole-metal-plug 116 and protection-plug 113; patterned electrode 117 electrically connected to through-hole-metal-plug 109 via half-through-hole-metal-plug 116; first type cladding layer 102, active layer 103 and second type cladding layer 104 in turn deposited between current spreading layer 114 and reflector/Ohmic/bonding layer 105.

An embodiment of through-hole vertical semiconductor devices or chips without static protection diode (FIG. 2) has substantially the same structure as that of FIG. 1f, except that there is no static protection diode built-in supporting substrate 206.

An embodiment of process of manufacturing through-hole vertical semiconductor devices or chips with static protection diodes is as the following:

(1) Forming a metalized silicon supporting wafer with static protection diodes built-in;

(2) Depositing a reflector/Ohmic/bonding layer on the second-type cladding layer of a semiconductor epitaxial wafer; then the first surface of the metalized silicon supporting wafer is bonded to the reflector/Ohmic/bonding layer to form a compound semiconductor epitaxial wafer;

(3) Removing the growth substrate of the semiconductor epitaxial wafer until the first-type cladding layer exposed;

(4) At pre-determined positions, etching the epitaxial layer until through-hole-metal-plugs and the silicon surface of the silicon supporting wafer exposed;

(5) Depositing protection-plugs on the exposed surfaces of both through-hole-metal-plugs and the silicon surface of the silicon supporting wafer, such that the exposed through-hole-metal-plugs do not directly electrically contact the reflector/Ohmic/bonding layer, the first-type cladding layer, the active layer and the second-type cladding layers;

(6) Depositing a current spreading layer on both the first-type cladding layer and the protection-plugs;

(7) Etching the current spreading layer and the protection-plugs until through-hole-metal-plugs exposed to form half-through-holes at pre-determined positions;

(8) Forming half-through-hole-metal-plugs in half-through-holes; half-through-hole-metal-plugs being electrically connected to through-hole-metal-plugs respectively;

(9) Depositing patterned electrodes on the surface of the current spreading layer; patterned electrodes being electrically connected to half-through-hole-metal-plugs respectively and, thus, through-hole-metal-plugs;

(10) Dicing the compound semiconductor epitaxial wafer to form semiconductor devices or chips.

The quantities and area of cross section of the through-hole-metal-plugs are pre-determined. The advantages of using plurality and larger cross section area of through-hole-metal-plugs are the following: (1) improving the heat dissipation efficiency further; (2) decreasing series electrical resistance and, thus, reducing the forward voltage and generating less heat.

The objects of the present invention are the following:
(1) The primary object is to provide through-hole vertical semiconductor (comprising GaN based, GaP based, GaNP based and ZnO based) devices or chips (comprising GaN based, GaP based, GaNP based and ZnO based LEDs) to resolve the above mentioned efficiency, burning-in and wire bonding issues.
(2) The second object is to provide a method for mass production of the through-hole vertical semiconductor devices or chips.
(3) The third object is to provide through-hole vertical semiconductor devices or chips with static protection diodes to resolve the above mentioned efficiency, burning-in and wire bonding issues.
(4) The fourth object is to provide a method for mass production of through-hole vertical semiconductor devices or chips with static protection diodes.
(5) The fifth object is to provide an embodiment of integration between semiconductor chips or devices with IC chips or devices.

Further objects and advantages of the present invention will become apparent from a consideration of the ensuing description and drawings.

### BRIEF DESCRIPTION OF THE SEVERAL VIEWS OF DRAWINGS

The novel features believed characteristic of the present invention are set forth in the claims. The invention itself, as well as other features and advantages thereof will be best understood by referring to detailed descriptions that follow, when read in conjunction with the accompanying drawings.

FIG. 1a to FIG. 1e show first embodiment of a method manufacturing through-hole vertical semiconductor devices or chips with built-in static protection diodes.

FIG. 1f shows first embodiment of a through-hole vertical semiconductor device or chip manufactured by the method of FIG. 1a to FIG. 1e.

FIG. 2 shows first embodiment of a through-hole vertical semiconductor device or chip without built-in static protection diode.

FIG. 3 shows second embodiment of through-hole vertical semiconductor devices or chips with built-in static protection diodes (FIG. 3c) and a method of manufacturing the same.

FIG. 4 shows third embodiment of through-hole vertical semiconductor devices or chips with built-in static protection diodes.

FIG. 5 shows second embodiment of a through-hole vertical semiconductor device or chip without built-in static protection diode.

FIG. 6 shows third embodiment of a through-hole vertical semiconductor device or chip without built-in static protection diode.

FIG. 7 shows an embodiment of a process manufacturing through-hole vertical semiconductor devices or chips with built-in static protection diodes.

FIG. 8 shows an embodiment of a process manufacturing through-hole vertical semiconductor devices or chips without built-in static protection diodes.

### DETAILED DESCRIPTION OF THE INVENTION

While embodiments of the present invention will be described below, the following description is illustrative the principle only and not limiting to the embodiments.

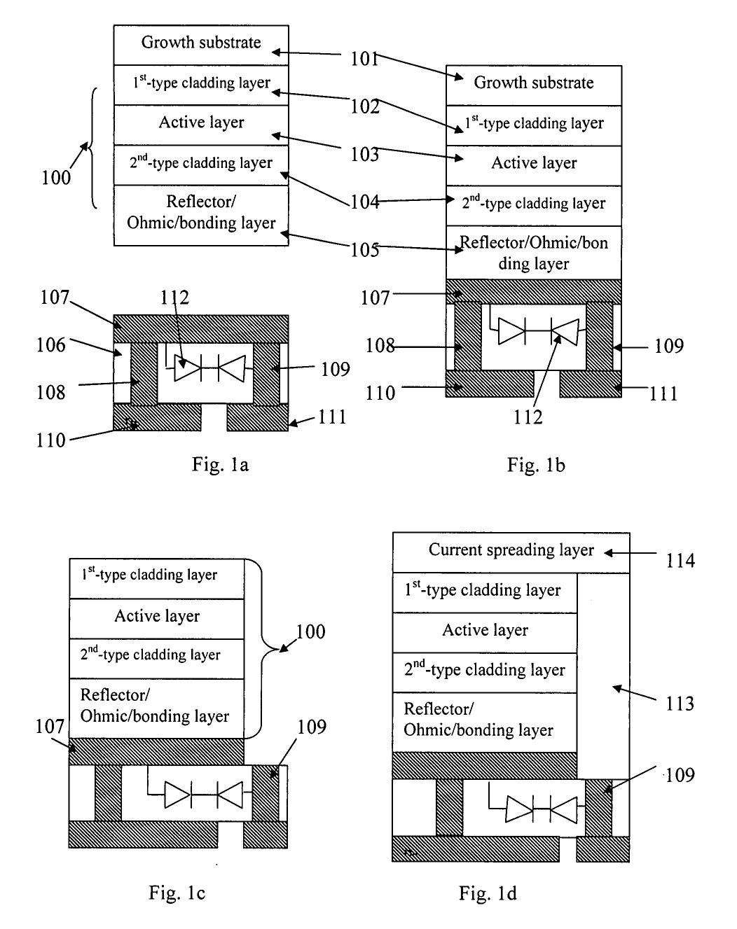

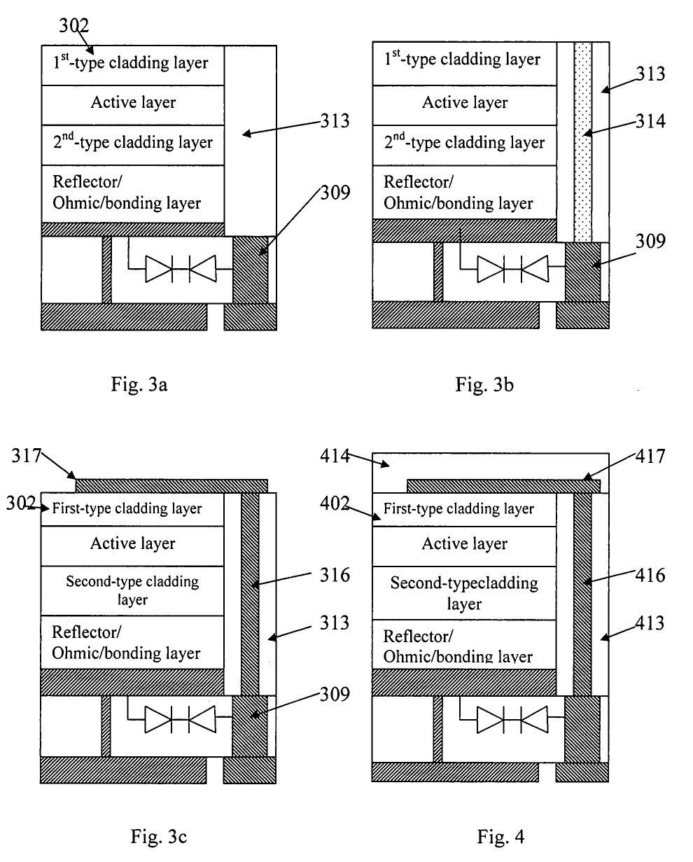

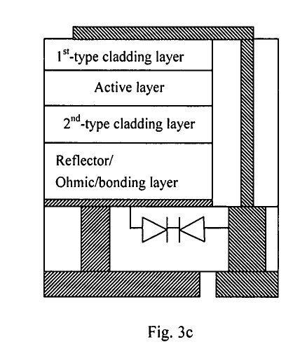

Note the followings:
(1) The present invention provides through-hole vertical semiconductor chips or devices (with and without built-in static protection diode) which are connected to external power source without wire bonding, can be burning-in before packaging, have higher reliability, and have thinner package of chips or devices.
(2) Since the structure of through-hole vertical semiconductor chips or devices of the present invention is the same for GaN based, GaP based, GaNP based and ZnO based semiconductor chips of devices, hereafter all of through-hole vertical GaN based, GaP based, GaNP based and ZnO based semiconductor chips of devices will be called “through-hole vertical semiconductor chip or device” without distinguishing semiconductor chips of devices with different material systems.
(3) Although a method of manufacturing through-hole vertical semiconductor chips or devices is the same for all of semiconductor chips of devices with different material systems, however, the detail conditions of process may be different for GaN based, GaP based, GaNP based and ZnO based semiconductor chips of devices.
(4) Through-hole vertical semiconductor devices or chips (with and without built-in static protection diode) of the present invention comprise: GaN based, GaP based, ZnO based and GaNP based semiconductor chips or devises. The material systems of GaN based chips or devises is selected from a group comprising the combinations of elements of Gallium, Aluminum, Indium and Nitrogen, which comprising GaN, GaInN, AlGaInN. The materials of GaP based semiconductor chips or devises is selected from a group comprising the combinations of elements of Gallium, Aluminum, Indium and Phosphor, which comprising GaP, GaInP, AlGaInP, InP. The materials of GaNP based semiconductor chips or devises is selected from a group comprising the combinations of elements of Gallium, Aluminum, Indium, Nitrogen and Phosphor, which comprising GaNP, GaInNP, AlGaNP, AlGaInNP. The materials of ZnO based chips or devises is selected from a group comprising the combinations of elements of Zinc and Oxygen, which comprising ZnO. GaN based, GaP based, ZnO based and GaNP based through-hole vertical semiconductor chips or devises comprise GaN based LED, GaP based LED, ZnO based LED and GaNP based LED. The crystal planes of GaN based epitaxial layers is selected from a group comprising c-plane, a-plane and m-plane.
(5) The manufacturing methods of through-hole vertical semiconductor devices or chips (with or without static protection diodes) of the present invention are at wafer level and the last process step is to dice the compound semiconductor wafer into individual chips or devices. Since a wafer includes a plurality of same chips or devices, in FIG. 1 and FIG. 3, using one chip or device to illustrate the manufacturing process.
(6) A metalized supporting wafer has the same size as that of the semiconductor epitaxial wafer. A metalized supporting sub-mount has the same size as that of a semiconductor chip.
(7) The present invention provides an embodiment of integration of a semiconductor chip or device and an IC device.
(8) There is no need to wire bond a patterned electrode to connect to an external power. The patterned electrode is electrically connected to the first electrode on the second surface of a supporting sub-mount via at least one half-through-hole-metal-plug and at least one through-hole-metal-plug. The metal layer on the first surface of the supporting sub-mount is bonded to the reflector/Ohmic/bonding layer, thus, through-hole vertical semiconductor chips or devices have all of advantages of a vertical chip or device, such as current crowding effect is substantially limited, higher current density can be employed, and the heat dissipation efficiency is higher.
(9) The capability of protecting static discharge is higher.
(10) The light extraction efficiency is higher because that there is a reflector/Ohmic/bonding layer between the second-type cladding layer and the supporting sub-mount.
(11) A patterned electrode can has different patterns so that the current will distribute more uniformly and block less output light.
(12) The area of a half-through-hole-metal-plug is smaller than that of a wire bonding pad, therefore less output light is blocked.

FIG. 1 shows first embodiment of a method manufacturing through-hole vertical semiconductor devices or chips with built-in static protection diodes. FIG. 1a: providing a semiconductor epitaxial wafer comprising: epitaxial layer 100 growing on growth substrate 101. Normally there is a buffer layer growing between growth substrate 101 and epitaxial layer 100. Since the buffer layer will be removed with growth substrate 101, FIG. 1 does not show the buffer layer. Epitaxial layer 100 comprises first-type cladding layer 102, active layer 103, second-type cladding layer 104. Electrically conductive reflector/Ohmic/bonding layer 105 is deposited on second-type cladding layer 104. The functions of reflector/Ohmic/bonding layer 105 are the following: (1) for LED, reflecting light, forming Ohmic contact, and bonding to the supporting wafer; (2) for other semiconductor devices or chips, forming Ohmic contact and bonding to the supporting wafer.

The structure of an active layer is selected from a group comprising bulk, single quantum well, multi-quantum well, quantum dot and quantum line. The material system of an epitaxial layer is selected from a group comprising: (1) the combinations of elements of Gallium, Aluminum, Indium and Nitrogen, which comprising GaN, GaInN, AlGaInN; (2) the combinations of elements of Gallium, Aluminum, Indium and Phosphor, which comprising GaP, GaInP, AlGaInP; (3) the combinations of elements of Gallium, Aluminum, Indium, Nitrogen and Phosphor, which comprising GaNP, GaInNP, AlGaInNP; (4) the combinations of elements of Zinc and Oxygen, which comprising ZnO. The crystal planes of GaN based epitaxial layer is selected from a group comprising c-plane, a-plane, and m-plane.

A silicon supporting wafer comprises: silicon supporting wafer 106, metal layer 107 deposited on the first surface of silicon supporting wafer 106, first electrode 111 and second electrode 110 both deposited on the second surface of silicon supporting wafer 106, static protection diode 112 built-in silicon supporting wafer 106, metal layer 107 electrically connected to second electrode 110 and first electrode 111 via through-hole-metal-plug 108 and through-hole-metal-plug 109 respectively.

FIG. 1b: bonding the semiconductor epitaxial wafer to the silicon supporting wafer to form a compound semiconductor epitaxial wafer. Metal layer 107 is bonded to reflector/Ohmic/bonding layer 105. The bonding process is performed at wafer level. The method of wafer bonding is selected from a group comprising: electrically conductive glue bonding, metal thermal-pressure bonding, fusion bonding. Since metal layer 107 and reflector/Ohmic/bonding layer 105 are bonded together, hereafter, call it reflector/Ohmic/bonding layer.

FIG. 1c: removing growth substrate 101 and the buffer layer, until first-type cladding layer 102 exposed. The removing method is different for different semiconductor epitaxial wafers. The method of removing growth substrate is selected from a group comprising laser lift off (suitable for transparent growth substrate comprising sapphire and SiC), dry/wet etching (suitable for growth substrate comprising silicon, GaAs, GaP), thermal separation, precision grinding/lapping (suitable for any growth substrate), and combination of about methods. An embodiment is the following: firstly, applying precision grinding/lapping method to thin down a growth substrate to pre-determined thickness then applying other method to completely removing the growth substrate.

Etching semiconductor epitaxial layer 100 and the reflector/Ohmic/bonding layer (including metal layer 107) at pre-determined positions, until the silicon surface of the silicon supporting substrate and the top surface of through-hole-metal-plug 109 exposed.

FIG. 1d: depositing protection-plug 113 on both the exposed silicon surface of the silicon supporting substrate and the exposed top surface of through-hole-metal-plug 109. The material of protection-plug 113 is selected from a group comprising SiO2. The top surface of protection-plug 113 is substantially at the same level as that of the top surface of the first-type cladding layer. Depositing current spreading layer 114 on both the top surfaces of first-type cladding layer 102 and protection-plug 113. The material of current spreading layer 114 is selected from a group comprising metals and electrically conductive oxides. The material of the electrically conductive oxides is selected from a group comprising ITO, ZnO:Al, ZnGa2O4, SnO2:Sb, Ga2O3:Sn, In2O3:Zn, NiO, MnO, CuO, SnO, GaO. The material of the transparent thin metal layer is selected from a group comprising Ni/Au, Ni/Pt, Ni/Pd, Ni/Co, Pd/Au, Pt/Au, Ti/Au, Cr/Au, Sn/Au.

FIG. 1e: Etching current spreading layer 114 and protection-plug 113 at pre-determined positions until the top surface of through-hole-metal-plug 109 exposed to form half-through-hole 115. The method of etching is selected from a group comprising dry etching and wet etching.

FIG. 1f: forming half-through-hole-metal-plug 116 in half-through-hole 115. Half-through-hole-metal-plug 116 is electrically connected to through-hole-metal-plug 109. Depositing patterned electrode 117 on the top surface of current spreading layer 114. Patterned electrode 117 is electrically connected to half-through-hole-metal-plug 116 and, thus, electrically connected to first electrode 111.

FIG. 1f also shows first embodiment of through-hole vertical semiconductor devices or chips with static protection diodes.

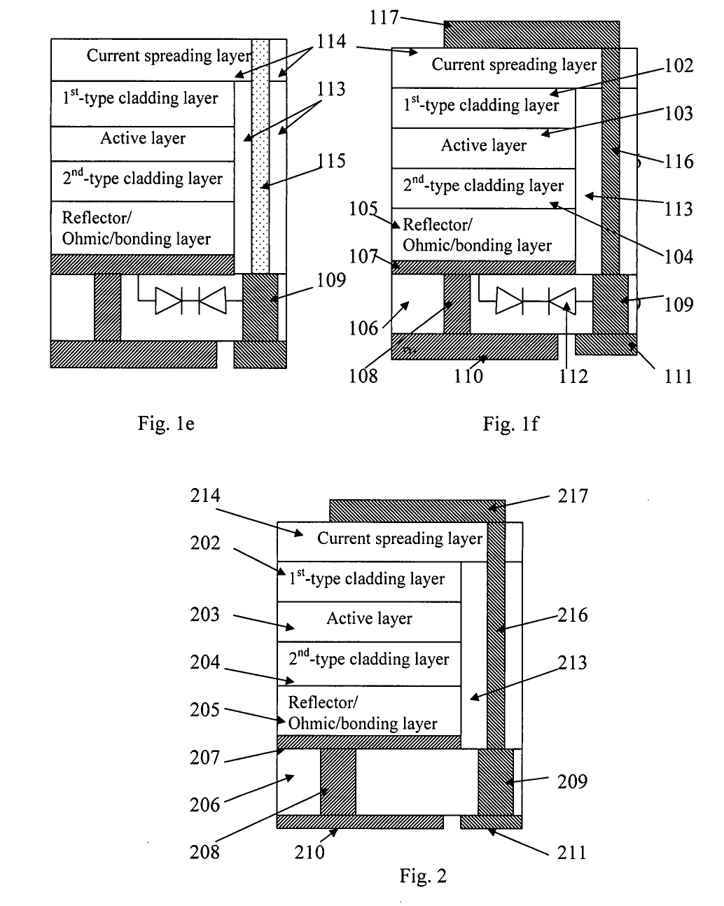

FIG. 2 shows first embodiment of through-hole vertical semiconductor devices or chips without built-in static protection diode. The structure and manufacturing process of the through-hole vertical semiconductor devices or chips without built-in static protection diode are substantially the same as that of the through-hole vertical semiconductor device or chip with built-in static protection diode of FIG. 1, except that there is no built-in static protection diode in the supporting wafer. Therefore, the material of the supporting wafers is selected from a group comprising silicon, AlN, GaAs, GaP, ZnO.

FIG. 3a to FIG. 3c shows second embodiment of method manufacturing through-hole vertical semiconductor devices or chips with built-in static protection diodes. Firstly repeating the process flow steps of FIG. 1a to FIG. 1c, then, performing the following process flow steps (FIG. 3a to 3c).

FIG. 3a: forming protection-plug 313 on the exposed surface of through-hole-metal-plug 309.

FIG. 3b: etching protection-plug 313 at pre-determined positions until the top surface of through-hole-metal-plug 309 exposed to form half-through-hole 314.

FIG. 3c: forming half-through-hole-metal-plug 316 in half-through-hole 314. Half-through-hole-metal-plug 316 is electrically connected to through-hole-metal-plug 309. Depositing patterned electrode 317 on the top surfaces of both first-type cladding layer 302 and protection-plug 313. Patterned electrode 317 is electrically connected to half-through-hole-metal-plug 316.

Note: optimizing the pattern of patterned electrode 317, the current spreading layer is not necessary. Thus there will be no issues of instability of the current spreading layer and emitting light blocked by thin metal current spreading layer.

FIG. 3c also shows second embodiment of through-hole vertical semiconductor devices or chips with static protection diodes.

FIG. 4 shows third embodiment of through-hole vertical semiconductor devices or chips with built-in static protection diodes. Its structure and manufacturing process are substantially the same as that of FIG. 3, except that there is a current spreading layer 414 deposited on the top surfaces of both patterned electrode 417 and first-type cladding layer 402.

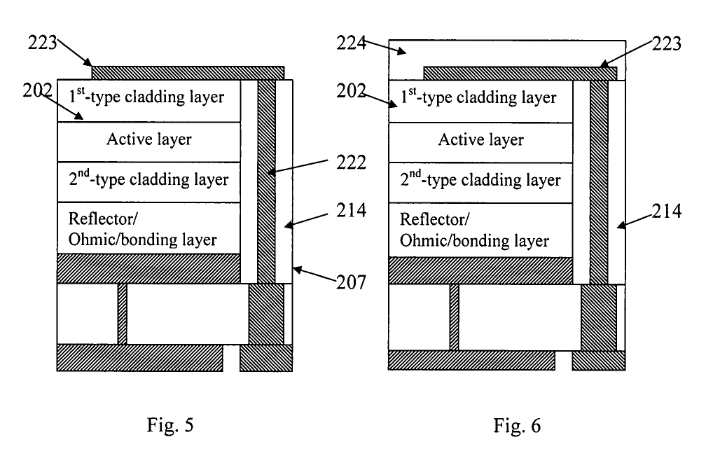

FIG. 5 shows second embodiment of through-hole vertical semiconductor devices or chips without built-in static protection diode. Its structure and manufacturing process are substantially the same as that of the through-hole vertical semiconductor device or chip with built-in static protection diode of FIG. 3, except that there is no built-in static protection diode in the supporting wafer. Therefore, the material of the supporting wafers is selected from a group comprising silicon, AlN, GaAs, GaP, ZnO.

FIG. 6 shows third embodiment of through-hole vertical semiconductor devices or chips without built-in static protection diode. Its structure and manufacturing process are substantially the same as that of the through-hole vertical semiconductor devices or chips with built-in static protection diode of FIG. 4, except that there is no built-in static protection diode in the supporting wafer. Therefore, the material of the supporting wafers is selected from a group comprising silicon, AlN, GaAs, GaP, ZnO.

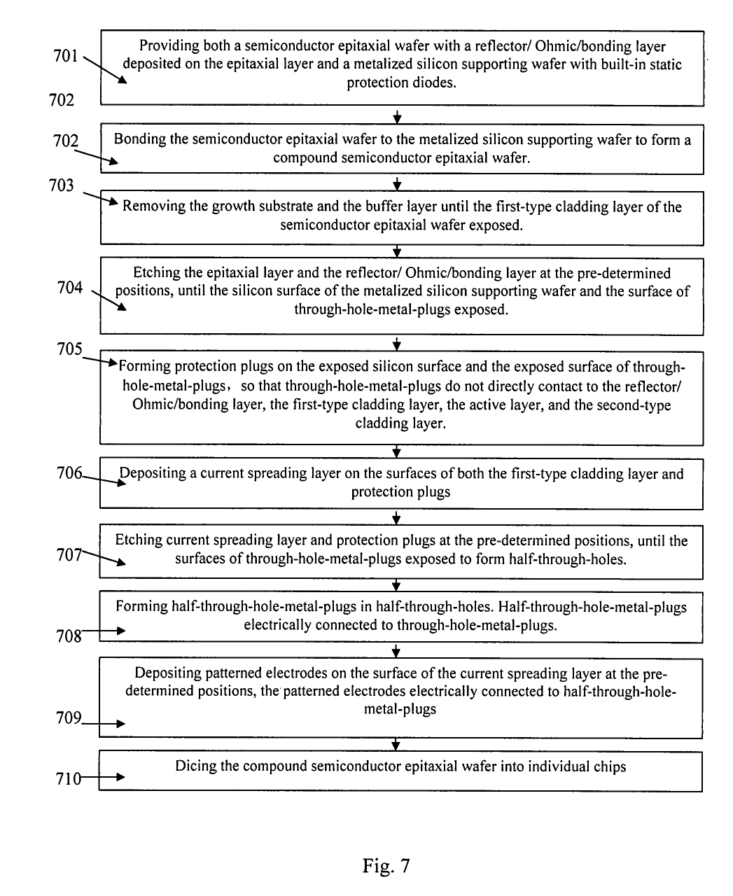

FIG. 7 shows schematically an embodiment of process flow steps of manufacturing through-hole vertical semiconductor devices or chips with having static protection diodes built-in.

Process step 701: providing a semiconductor epitaxial wafer and a silicon supporting wafer. Forming a plurality of static protection diodes inside of the silicon supporting wafer. Depositing a metal layer on first side of the silicon supporting wafer. The metal layer on the first side of the silicon supporting wafer is electrically connected to one polarity of built-in static protection diodes. Forming a plurality of electrode set at pre-determined positions on the second side of the silicon supporting wafer. Each of electrode set has first and second electrodes. Forming a plurality of through-hole-metal-plugs passing through the silicon supporting wafer and electrically connecting first and second electrodes to the metal layer on the first side on the silicon supporting wafer respectively.

Depositing a reflector/Ohmic/bonding layer on the second-type cladding layer of the semiconductor epitaxial wafer.

Process step 702: bonding the reflector/Ohmic/bonding layer to the metal layer of the silicon supporting wafer to form a compound semiconductor epitaxial wafer. The method of bonding is selected from a group comprising electrically conductive glue bonding, metal thermal-pressure bonding, fusion bonding. After bonding, the reflector/Ohmic/bonding layer and the metal layer become one layer, hereafter call it the reflector/Ohmic/bonding layer.

Process step 703: removing the growth substrate and the buffer layer of the semiconductor epitaxial wafer until the first-type cladding layer exposed. The method of removing the growth substrate is selected from a group comprising laser lift-off, precision grinding/polishing, thermal separation, etching, and combination of above methods. The laser lift-off method is suitable for transparent growth substrates comprising sapphire and SiC. The precision grinding/polishing method is suitable for all of growth substrates comprising silicon, GaAs, GaP, sapphire and SiC. The etching method is suitable for selective-etching growth substrates comprising silicon, GaAs, and GaP.

Process step 704: at pre-determined positions, etching the semiconductor epitaxial layer (comprising the first-type cladding layer, the active layer, the second-type cladding layer) and the reflector/Ohmic/bonding layer until both the top surfaces of the through-hole-metal-plugs and the silicon surface of the silicon supporting wafer exposed. The etching method is selected from a group comprising dry and wet etching.

Process step 705: Depositing a protection-plug on both the exposed top surfaces of the through-hole-metal-plugs and the exposed silicon surface of the silicon supporting wafer so that the through-hole-metal plugs do not contact the reflector/Ohmic/bonding layer and the epitaxial layer (comprising the first-type cladding layer, the active layer and the second-type cladding layer). The material of the protection-plug is selected from a group comprising SiO2. The top surfaces of the protection-plugs are substantially at the same level as that of the first-type cladding layer.

Process step 706: Depositing a current spreading layer on the top surfaces of both the first-type cladding layer and the protection-plugs. The material of the current spreading layer is selected from a group comprising transparent and electrically conductive oxide layer and transparent thin metal layers. The material of the transparent and electrically conductive oxide layer is selected from a group comprising ITO, ZnO:Al, ZnGa2O4, SnO2:Sb, Ga2O3:Sn, In2O3:Zn, NiO, MnO, CuO, SnO and GaO. The material of the transparent thin metal layer is selected from a group comprising Ni/Au, Ni/Pt, Ni/Pd, Ni/Co, Pd/Au, Pt/Au, Ti/Au, Cr/Au and Sn/Au.

Process step 707: at pre-determined positions, etching the current spreading layer and the protection-plugs until the top surfaces of half-through-hole-metal-plugs exposed and forming half-through-holes. The methods of etching comprise dry and wet etching.

Process step 708: Forming half-through-hole-metal-plugs in half-through-holes. Half-through-hole-metal-plugs are electrically connected to the through-hole-metal-plugs.

Process step 709: at pre-determine positions on the surfaces of the current spreading layer, forming optimized patterned electrodes which being electrically connected to the half-through-hole-metal-plugs so that the current distribution is more uniform.

Process 710: dicing the compound semiconductor epitaxial wafer into single through-hole vertical semiconductor devices or chips.

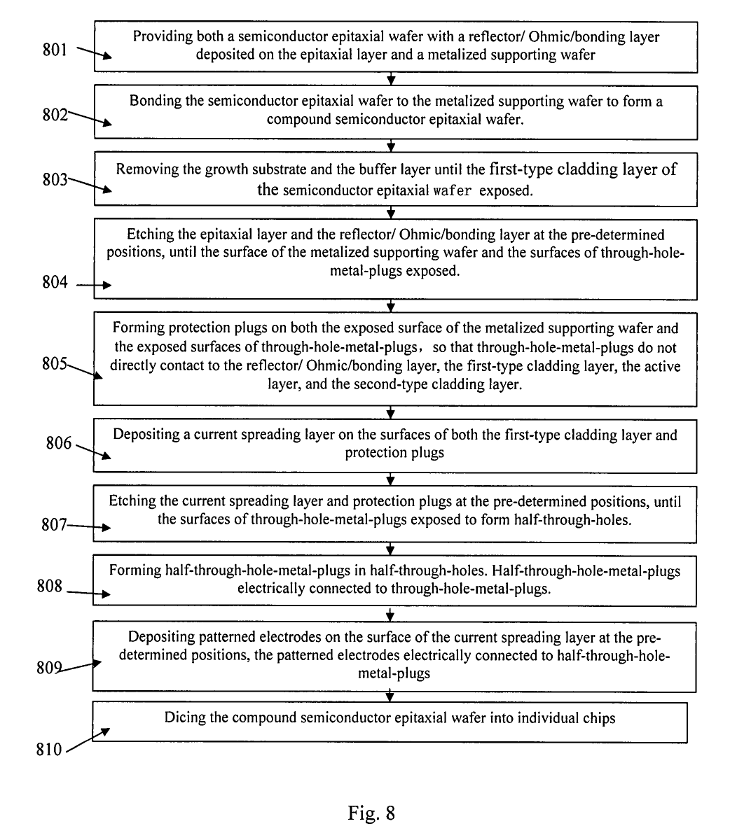

FIG. 8 shows schematically an embodiment of process flow steps of manufacturing through-hole vertical semiconductor devices or chips without having static protection diodes built-in. The process flow steps are substantially the same as that of FIG. 7, except that (1) there is no static protection diode built-in the supporting wafer and, thus, (2) the material of the supporting wafer is selected from a group comprising silicon, AlN, GaAs, ZnO.

Although the description above contains many specifications, these should not be construed as limiting the scope of the present invention but as merely providing illustrations of some of the presently preferred embodiments of the present invention. Therefore the scope of the present invention should be determined by the claims and their legal equivalents, rather than by the embodiments given.

We claim:

1. A through-hole vertical semiconductor device or chip comprising:
a supporting sub-mount; wherein a metal layer deposited on first surface of said supporting sub-mount; wherein first and second electrodes formed on second surface of said supporting sub-mount; wherein said second electrode electrically connected to said metal layer via at least one through-hole-metal-plug passing through said supporting sub-mount;
a semiconductor epitaxial layer; wherein said semiconductor epitaxial layer being bonded to said metal layer on said first surface of said supporting sub-mount; wherein the surface of said semiconductor epitaxial layer bonded to said metal layer being electrically connected to said second electrode on said second surface of said supporting sub-mount via said metal layer and at least one said through-hole-metal-plug;
at least one protection plug passing through said semiconductor epitaxial layer; wherein a half-through-hole passing through said protection plug;
a half-through-hole-metal-plug formed in said half-through-hole; wherein said at least one half-through-hole-metal-plug electrically connected to at least one through-hole-metal-plug which electrically connected to said first electrode on said second surface of said supporting sub-mount;
a patterned electrode deposited on the surfaces of said semiconductor epitaxial layer and said protection plug; wherein said patterned electrode being electrically connected to said first electrode on said second surface of said supporting sub-mount via both at least one said half-through-hole-metal-plug and at least one said through-hole-metal-plug.

2. The through-hole vertical semiconductor device or chip of claim 1, wherein the material of said supporting sub-mount is selected from a group comprising silicon, AlN, GaAs, GaP.

3. The through-hole vertical semiconductor device or chip of claim 2, wherein said silicon supporting sub-mount is selected from a group comprising silicon supporting sub-mounts with built-in static protection diodes and silicon supporting sub-mounts without built-in static protection diodes.

4. The through-hole vertical semiconductor device or chip of claim 3, wherein the two polarities of said built-in static protection diode being electrically connected to said first and second electrodes on said second surface of said supporting sub-mount respectively.

5. The through-hole vertical semiconductor device or chip of claim 1, wherein the material of said semiconductor epitaxial layer is selected from a group comprising: (1) GaN based materials comprising combinations of elements of gallium, aluminum, indium and nitrogen, comprising GaN, AlGaN, GaInN and AlGaInN; wherein the crystal plane of said GaN based epitaxial layer being selected from a group comprising c-plane, m-plane and a-plane; (2) GaP based materials comprising combination of elements of gallium, aluminum, indium and phosphor, comprising GaP, AlGaP, GaInP and AlGaInP; (3) GaPN based materials comprising combinations of elements of gallium, aluminum, indium, nitrogen and phosphor, comprising GaNP, AlGaNP, GaInNP and AlGaInNP; (4) ZnO based materials comprising ZnO.

6. The through-hole vertical semiconductor device or chip of claim 1, wherein said semiconductor epitaxial layer comprises a first-type cladding layer, an active layer and a second-type cladding layer.

7. The through-hole vertical semiconductor device or chip of claim 6, wherein the structure of said active layer is selected from a group comprising bulk, single quantum well, multiple quantum well, quantum dot and quantum line.

8. The through-hole vertical semiconductor device or chip of claim 6, wherein the material of said semiconductor epitaxial layer is selected from a group comprising:
(1) GaN based materials comprising combinations of elements of gallium, aluminum, indium and nitrogen, comprising GaN, AlGaN, GaInN and AlGaInN;
wherein the crystal plane of said GaN based epitaxial layer being selected from a group comprising c-plane, m-plane and a-plane; (2) GaP based materials comprising combination of elements of gallium, aluminum, indium and phosphor, comprising GaP, AlGaP, GaInP and AlGaInP; (3) GaPN based materials comprising combinations of elements of gallium, aluminum, indium, nitrogen and phosphor, comprising GaNP, AlGaNP, GaInNP and AlGaInNP; (4) ZnO based materials comprising ZnO.

9. The through-hole vertical semiconductor device or chip of claim 1, wherein the quantity of said through-hole-metal-plugs connecting said second electrode to said metal layer is more than one.

10. The through-hole vertical semiconductor device or chip of claim 1, wherein the quantity of said half-through-hole-metal-plugs connecting said patterned electrode to said through-hole-metal-plugs is more than one.

11. The through-hole vertical semiconductor device or chip of claim 1, wherein the material of said protection plugs is selected from a group comprising SiO2.

12. The through-hole vertical semiconductor device or chip of claim 1, further comprising a reflector/Ohmic/bonding layer deposited between said semiconductor epitaxial layer and said metal layer of said supporting sub-mount; wherein said semiconductor epitaxial layer being electrically connected to said second electrode on said second surface of said supporting sub-mount via both said reflector/Ohmic/bonding layer and at least one said through-hole-metal-plug.

12. The through-hole vertical semiconductor device or chip of claim 1, further comprising a current spreading layer; wherein said current spreading layer deposited between said semiconductor epitaxial layer and said patterned electrode;
wherein said half-through-hole-metal-plugs passing through said current spreading layer and said protection plugs and connecting said patterned electrode to said through-hole-metal-plugs.

13. The through-hole vertical semiconductor device or chip of claim 12, wherein the material of said current spreading layer is selected from a group comprising metals and electrically conductive oxides; wherein the material of said electrically conductive oxides being selected from a group comprising ITO, ZnO:Al, ZnGa2O4, SnO2:Sb, Ga2O3:Sn, In2O3:Zn, NeeeeiO, MnO, CuO, SnO, GaO; wherein the material of the transparent thin metal layer being selected from a group comprising Ni/Au, Ni/Pt, Ni/Pd, Ni/Co, Pd/Au, Pt/Au, Ti/Au, Cr/Au, Sn/Au.

14. The through-hole vertical semiconductor device or chip of claim 1, further comprising a current spreading layer; wherein said current spreading layer deposited on the top surfaces of both said semiconductor epitaxial layer and said patterned electrode.

15. The through-hole vertical semiconductor device or chip of claim 14, wherein the material of said current spreading layer is selected from a group comprising metals and electrically conductive oxides; wherein the material of said electrically conductive oxides being selected from a group comprising ITO, ZnO:Al, ZnGa2O4, SnO2:Sb, Ga2O3:Sn, In2O3:Zn, NiO, MnO, CuO, SnO, GaO; wherein the material of the transparent thin metal layer being selected from a group comprising Ni/Au, Ni/Pt, Ni/Pd, Ni/Co, Pd/Au, Pt/Au, Ti/Au, Cr/Au, Sn/Au.

16. A manufacturing method produces said through-hole vertical semiconductor devices or chips of claim 1.

17. The manufacturing method of claim 16 comprises the following process flow steps:
(1) providing a semiconductor epitaxial wafer and a supporting wafer; depositing a metal layer on the first side of said supporting wafer; forming a plurality of electrode sets at pre-determined positions on said second side of said supporting wafer; each of said electrode sets having a first and a second electrodes; forming a plurality of through-hole-metal-plugs passing through said supporting wafer and electrically connecting said first and said second electrodes to said metal layer on said first side of said supporting wafer respectively;
(2) bonding said supporting wafer to said semiconductor epitaxial wafer to form a compound semiconductor epitaxial wafer;
(3) removing the growth substrate of said semiconductor epitaxial wafer and the buffer layer until the first-type cladding layer of said semiconductor epitaxial wafer exposed;
(4) etching said semiconductor epitaxial layer at pre-determined positions until the surfaces of said supporting wafer and said through-hole-metal-plugs exposed;
(5) depositing a protection-plug on both said surface of said through-hole-metal-plugs and said surface of said supporting wafer so that said through-hole-metal-plugs not contact said reflector/Ohmic/bonding layer and said semiconductor epitaxial layer;
(6) etching said protection plugs at pre-determined positions until the surfaces of said through-hole-metal-plugs exposed to form half-through-holes;
(7) forming half-through-hole-metal-plugs in said half-through-holes;
(8) at pre-determine positions on the surfaces of said semiconductor epitaxiahayer, said protection plugs and said half-through-hole-metal-plugs, depositing patterned electrodes which being electrically connected to said half-through-hole-metal-plugs;
(9) dicing said compound semiconductor epitaxial wafer into individual through-hole vertical semiconductor devices or chips.

18. The manufacturing method of claim 17, further comprises the following process flow step: forming a plurality of static protection diodes inside of said supporting wafer.

19. The manufacturing method of claim 17, further comprises the following process flow step: depositing a reflector/Ohmic/bonding layer between said metal layer and said semiconductor epitaxial layer of said semiconductor epitaxial wafer.
